(19) United States
(12) Patent Application Publication
(10) Pub. No.: US 2010/0181636 A1
(43) Pub. Date: Jul. 22, 2010

(54) OPTICAL DEVICE, SOLID-STATE IMAGING DEVICE, AND METHOD OF MANUFACTURING OPTICAL DEVICE

(75) Inventors: Yoshiki TAKAYAMA, Shiga (JP); Tetsumasa MARUO, Osaka (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/686,783

(22) Filed: Jan. 13, 2010

(30) Foreign Application Priority Data
Jan. 20, 2009 (JP) 2009-010423
Sep. 9, 2009 (JP) 2009-208725

(51) Int. Cl. H01L 31/0232; H01L 31/18

(52) U.S. Cl. 257/432; 438/65; 257/E31.127

(57) ABSTRACT

An optical device includes the following structures. An optical element includes a light-receiving element at an upper surface of the optical element. A transparent member is disposed on the upper surface to cover the light-receiving element. A case includes a bottom wall, a side wall protruding from an outer edge of the bottom wall, and a through-hole penetrating the bottom wall. A sealant is filled in a space defined by surfaces of the optical element, the transparent member, and the case, and also in the through-hole. Here, the optical element and the transparent member are stored in a region between the bottom wall and the side wall. The sealant is filled to the region to seal the space. The bottom wall is segmented into: a center region in which the optical element is placed; and a peripheral region outside the center region. The through-hole is arranged in the peripheral region.

### BACKGROUND OF THE INVENTION

(1) Field of the Invention

The present invention relates to optical devices, and more particularly to a technology of preventing detachment of a sealant that prevents undesired incident light and reflected light from entering a light-receiving unit so as to ensure reliability of moisture resistance or the like.

(2) Description of the Related Art

In recent years, miniaturization of electronic devices is increasingly accelerated and optical devices used in the electronic devices are no exception. There is a demand for further miniaturization of optical devices. Thus, the conventional optical devices have a structure in which an optical element is stored in a recessed package (container or case) and the opening of the package is sealed using a protection glass or the like (hereinafter, referred to as a “transparent member”). In the field of such conventional optical devices, there have been developed optical devices having a structure in which the transparent member is adhered directly on the optical element, thereby making the optical devices smaller and thinner.

However, such a structure having a transparent member directly adhered to an optical element reduces the distance between an end surface (outer edge surface) of the transparent member and the light-receiving unit of the optical element. As a result, undesired incident light is likely to enter the light-receiving unit from the end surface of the transparent member, which causes poor image such as flare and a ghost.

In order to prevent such entering of the incident light from the outside of the end surface of the transparent member, various structures have been conceived, such as a light-shielding layer is formed on the end surface of the transparent member, and a structure in which a size of the transparent member is larger than a size of the light-receiving units of the optical element. It is also known that the optical element directly adhered with the transparent member is stored being adhered to a bottom of the recessed package, and an internal side surface of the recessed package is provided with a step that is higher than a die attach part. The step is provided with a wire bond pad made of a gold plate or the like, and the wire bond pad is electrically connected to a pad of the optical element using an Au wire. Still further, it has been disclosed a technology of filing light-shielding resin in the recessed package to cover the entire end surface of the transparent member with the light-shielding resin, so as to prevent undesired incident light from entering from the end surface (refer to Japanese Unexamined Patent Application Publication No. 2007-142194, for example).

However, in the method of storing the optical element directly adhered with the transparent member into the recessed package and covering the entire end surface of the transparent member with the light-shielding resin filled in the recessed package, there is the following problem. Since a linear expansion coefficient of the light-shielding resin is greater than a linear expansion coefficient of the recessed package, stress of the light-shielding resin is concentrated towards an opening of the recessed package when a high temperature is applied due to reflow mounting on mounting boards. More specifically, the concentration of the stress applied in an upward direction produces locations having a low adherence degree between the recessed package and the light-shielding resin. The locations are interfaces between (a) a gold-plated part as a wire bond pad of the recessed package and (b) the light-shielding resin. At the locations, the light-shielding resin is detached from the gold-plated part. In addition, the detachment at the locations causes a wire of the wire bond pad to be pulled by the light-shielding resin, which breaks the wire and eventually produces electrical defects.

### SUMMARY OF THE INVENTION

Thus, the present invention addresses the above-described problems. It is an object of the present invention to provide an optical device having a structure in which an optical element directly adhered to a transparent member is stored in a recessed package, being adhered to a bottom of the recessed package, and the recessed package is filled with light-shielding resin. The structure prevents the light-shielding resin from being detached from the recessed package at an interface between the light-shielding resin and the recessed package due to thermal stress.

In accordance with an aspect of the present invention for achieving the object, there is provided an optical device including: an optical element including a light-receiving element as a part of an upper surface of the optical element; a transparent member disposed on the upper surface of the optical element so as to cover the light-receiving element; a case including a bottom wall, a side wall protruding from an outer edge of the bottom wall, and a through-hole penetrating the bottom wall, the optical element and the transparent member being stored in a region between the bottom wall and the side wall; and a sealant filled in (a) a space defined by surfaces of the optical element, the transparent member, and the case, and (b) the through-hole, the sealant being filled to the region to seal the space, wherein the bottom wall of the case is segmented into (a) a center region in which the optical element is placed and (b) a peripheral region outside the center region, and the through-hole is arranged in the peripheral region.

With the above structure, since the sealant is filled also in the through-hole formed in the bottom wall of the case, stress caused by a difference in linear expansion coefficients between the case and the sealant is dispersed upwards and downwards. As a result, it is possible to efficiently prevent the sealant from being detached from the case at an interface between the sealant and the case (especially at an interface between the sealant and an electrode part). Here, a shape of the through-hole formed in the bottom wall of the case is not limited. The larger an area of the through-hole is, the more the stress applied on the sealant is dispersed. Therefore, optimum shape, size, number, and the like of the through-holes can be determined depending on a strength, dimensions, and the like of the package (case). In addition, if the through-hole are arranged in the peripheral region of the bottom wall, the sealant may be filed into the case after adhering the optical element to the case, which simplifies processing for filing the sealant. Further, the sealant may be made of a light-shielding material.

With the above structure, incident light is prevented from entering the end surface of the transparent member. When the sealant is filled to enhance moisture resistance or corrosion resistance, the sealant may be transparent resin.

Furthermore, the through-hole may be arranged across the peripheral region and the center region of the bottom wall. Still further, said through-hole may extend to under said side wall. With the above structure, a total area of the through-hole is significantly increased. As a result, stress applied on the sealant can be further dispersed.

In accordance with another aspect of the present invention, there is provided a solid-state imaging device including: a solid-state imaging element including a light-receiving element as a part of an upper surface of the solid-state imaging element; a transparent member disposed on the upper surface of the solid-state imaging element so as to cover the light-receiving element; a case including a bottom wall, a side wall protruding from an outer edge of the bottom wall, and a through-hole penetrating the bottom wall, the solid-state imaging element and the transparent member being stored in a region between the bottom wall and the side wall; and a sealant filled in (a) a space defined by surfaces of the solid-state imaging element, the transparent member, and the case, and (b) the through-hole, the sealant being filled to the region to seal the space, wherein the bottom wall of the case is segmented into (a) a center region in which the solid-state imaging element is placed and (b) a peripheral region outside the center region, and the through-hole is arranged in the peripheral region.

In accordance with still another aspect of the present invention, there is provided a method of manufacturing the optical device described above. The method of manufacturing the optical device, the optical device including: an optical element including a light-receiving element as a part of an upper surface of the optical element; a transparent member disposed on the upper surface of the optical element so as to cover the light-receiving element; a case including a bottom wall, a side wall protruding from an outer edge of the bottom wall, and a through-hole penetrating the bottom wall, the optical element and the transparent member being stored in a region between the bottom wall and the side wall; and a sealant filled in (a) a space defined by surfaces of the optical element, the transparent member, and the case, and (b) the through-hole, the sealant being filled to the region to seal the space, wherein the bottom wall of the case is segmented into (a) a center region in which the optical element is placed and (b) a peripheral region outside the center region, and the through-hole is arranged in the peripheral region, the method includes: adhering a bottom surface of the optical element on which the transparent member is deposited to the bottom wall of the case; blocking the through-hole at a bottom surface of the bottom wall; and filing the sealant into the region between the bottom wall and the side wall of the case. Thereby, it is possible to efficiently prevent the sealant from leaking from the through-hole when the material of the sealant is being filled.

According to the present invention, in an optical device having a structure in which an optical element directly adhered to a transparent member is stored in a case (recessed package) by being adhered to a bottom of the case and the case is filled with a sealant (light-shielding resin), the sealant is filled also in a through-hole formed in the bottom wall of the case. Thereby, even if reflow mounting or the like produces heat to cause a difference in linear expansion coefficients between the case (recessed package) and the sealant (light-shielding resin), it is possible to prevent the sealant from being detached from the case at an interface between the case and the sealant. As a result, high reliability can be achieved.

### FURTHER INFORMATION ABOUT TECHNICAL BACKGROUND TO THIS APPLICATION

The disclosure of Japanese Patent Application No. 2009-010423 filed on Jan. 20, 2009, and No. 2009-208725 filed on Sep. 9, 2009 including specification, drawings and claims is incorporated herein by reference in its entirety.

### BRIEF DESCRIPTION OF THE DRAWINGS

These and other objects, advantages and features of the present invention will become apparent from the following description thereof taken in conjunction with the accompanying drawings that illustrate specific embodiments of the present invention. In the

Drawings:

FIG. 1A is a plan view of an optical device according to a first embodiment of the present invention.

FIG. 1B is a cross-sectional view of the optical device according to the first embodiment of the present invention.

FIG. 2 is a view showing an example of shapes of through-holes.

FIG. 3 is a view showing another example of shapes of the through-holes.

FIG. 4 is a view showing an example of increasing areas of the through-holes.

FIG. 5A is a view of a state where the through-holes are sealed, explaining a method of manufacturing the optical device according to the first embodiment of the present invention.

FIG. 5B is a view of a state where a material of a sealant is filled into a case, explaining the method of manufacturing the optical device according to the first embodiment of the present invention.

FIG. 5C is a view of a state where shielding of the through-holes is removed, explaining the method of manufacturing the optical device according to the first embodiment of the present invention.

### DESCRIPTION OF THE PREFERRED EMBODIMENT(S)

Hereinafter, an embodiment of the present invention is described with reference to the drawings.

### First Embodiment

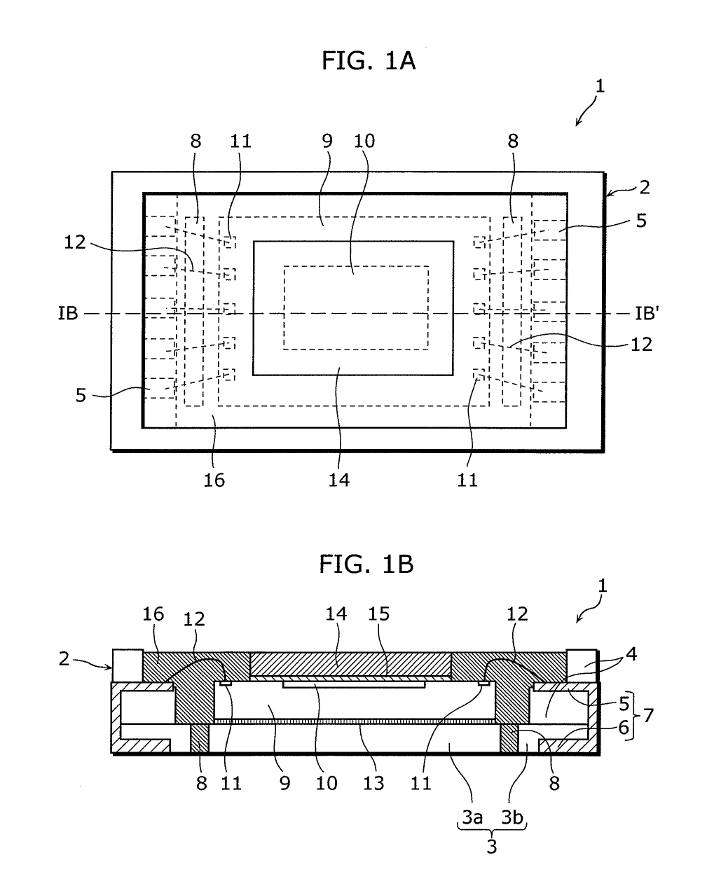

FIG. 1A is a plan view of an optical device according to the first embodiment of the present invention. FIG. 1B is a cross-sectional view taken along line IB-IB′ of the optical device shown in FIG. 1A.

As shown in FIGS. 1A and 1B, the optical device 1 primarily includes a case (optical element support) 2, an optical element 9, a transparent member 14, and a sealant 16. The optical device 1 is typically a solid-state imaging device.

The case 2 is a recessed member structured with a bottom wall 3 having a rectangular shape and a side wall 4 protruding upwards from an outer edge of the bottom wall 3. The case 2 stores the optical element 9 and the transparent member 14 in a region (space) defined by the bottom wall 3 and the side wall 4. The case 2 further has lead parts 7 each consisting of an internal electrode 5 and an internal electrode 6. The internal electrode 5 is exposed to an inside surface of the side wall 4. The external electrode 6 is exposed to a bottom surface (under side) of the bottom wall 3. The surfaces of the lead parts 7 are plated with gold (Au) or the like.

The bottom wall 3 of the case 2 is provided with a plurality of through-holes 8 each penetrating the bottom wall 3 in a thickness direction (in a vertical direction in FIG. 1B). Here, the bottom wall 3 of the case 2 is segmented into a center region 3 and a peripheral region 3b. The center region 3a is a region in which the optical element 9 is placed on the bottom wall 3. The peripheral region is a region outside the center region 3a in which the optical element 9 is placed. In other words, the peripheral region surrounds the center region 3a. Each of the through-holes 8 in the first embodiment is a rectangular long hole arranged in the peripheral region 3b of the bottom wall 3, more specifically, arranged along narrow sides of the rectangular bottom wall 3

The optical element 9 includes a light-receiving unit 10 and a plurality of electrode parts 11. The light-receiving unit 10 is formed at the center of the upper surface of the optical element 9. The plurality of electrode parts 11 are formed at the outer edge of the upper surface of the optical element 9. The electrode parts 11 are electrically connected to the light-receiving unit 10, and each of the electrode parts 11 is also electrically connected to a corresponding internal electrode 5 of the case 2 via a corresponding wire 12. An example of the optical element 9 is an image sensor (solid-state imaging device). That is to say, the light-receiving unit 10 includes a plurality of photodiodes which respectively corresponding to pixels and are arranged in a matrix.

The optical element 9 is adhered to the bottom wall 3 of the case using die bonding (DB) material 13. In more detail, the optical element 9 is adhered to the center region 3a of the bottom wall 3. Therefore, the through-holes in the first embodiment are formed in a region different from the region where the optical element 9 is placed. In other words, the through-holes 8 and the optical element 9 do not overlap with each other, when the optical device 1 is viewed from a direction perpendicular to the bottom wall 3 (upwards in FIG. 1B).

The transparent member 14 is a substantially rectangular flat plate member which is smaller than the optical element 9 but larger than the light-receiving unit 10. The transparent member 14 is disposed on the upper surface of the optical element 9 to cover the light-receiving unit 10. The material of the transparent member 14 may be glass, an inside radius (IR) cut filter, or an optical low-pass filter, for example, but is generally glass. The transparent member 14 has an upper surface that is exposed, and a bottom surface that is adhered to the upper surface of the optical element 9 using a resin adhesive 15. As the resin adhesive 15, a transparent resin material such as an acrylate resin, an epoxy resin, or a silicon resin is used.

The sealant 16 fills the inside of the case 2 to seal a space defined by the surfaces of the optical element 9, the transparent member 14, and the case 2, and also fills the through-holes 8. In other words, the sealant 16 contacts the internal wall surfaces of the case 2, the surfaces of the internal electrodes 5, the internal wall surfaces of the through-holes 8, the surfaces of the optical element 9 and the transparent member 14. Therefore, an interface are formed between the sealant 16 and each of the surfaces.

The sealant 16 is desirably made of a light-shielding material, when the sealant 16 is filled to prevent light from entering from the end surface of the transparent member 14. On the other hand, when the sealant 16 is used to enhance reliability of the optical device, such as moisture resistance or corrosion resistance of the internal electrodes 5, the sealant 16 may be transparent resin. Examples of the transparent resin are an acrylate resin, an epoxy resin, an silicon resin, and the like.

Here, the sealant 16 which is generally made of resin or the like has a linear expansion coefficient grater than a linear expansion coefficient of the case 2 made of ceramic or the like. However, since the sealant 16 is filled in the through-holes 8 formed in the bottom wall 3 of the recessed case 2, stress applied on the sealant 16 is not concentrated only upwards towards there is an opening but is applied also downwards towards the through-holes 8 even when reflow mounting on a mounting board, for example, produces a high temperature. As a result, the stress applied upwards is dispersed and reduced, and eventually detachment between the sealant 16 and the recessed case 2 can be prevented.

Especially, the adherence degree between each gold-plated part of the internal electrodes 5 and the sealant 16 is weaker than that of any other parts. In addition, detachment at the interface between the internal electrode 5 and the sealant 16 would remove the wire 12 and eventually cause connection defects. The electrode parts 11 of the optical element 9 also have the same problem. In order to solve the problem, the above-described structure prevents the detachment at the interfaces, thereby effectively preventing connection defects.

In the first embodiment, the through-hole 8 is arranged between the internal electrodes 5 and the electrode parts 11, in other words, arranged in a region below the wires 12. Thereby, it is possible to further effectively prevent the detachment at the interface between each internal electrode 5 and the sealant 16 and at the interface between each electrode part 11 and the sealant 16.

Here, a position and a shape of the through-hole 8 are not limited. For example, the through-hole 8 may be a cylinder, a rectangular column, or a trench. In addition, an area of the through-hole 8 and the number of the through-holes 8 are not limited. Each of the through-holes 8 may have a shape suitable for the design of the optical device 1. However, the larger the area of the through-hole 8 is, the more the stress applied on the sealant 16 can be dispersed.

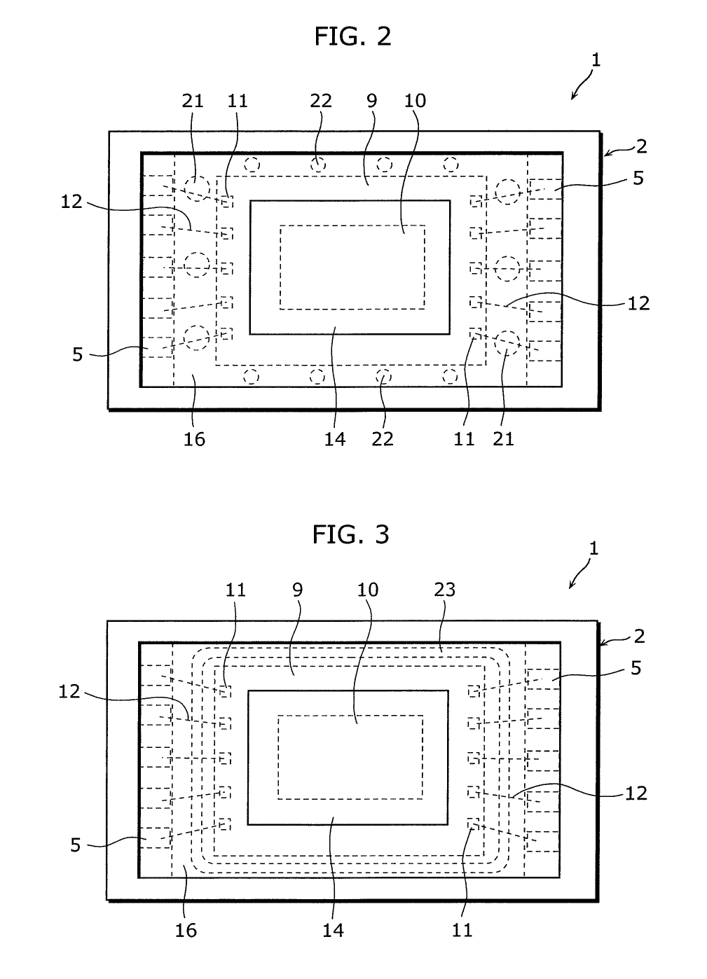

Other examples of the through-holes formed in the bottom wall 3 of the case 2 are described with reference to FIGS. 2 to 4. Here, the same reference numerals of FIG. 1 are assigned to the identical elements of FIGS. 2 to 4, so that the identical elements are not explained again below.

Firstly, in a variation of the optical device 1 which is shown in FIG. 2, through-holes 21 and 22 each having a cylinder shape are provided at a plurality of positions of the bottom wall 3. In the variation of the first embodiment, each of areas of the peripheral region 3b which are located along the narrow sides of the bottom wall 3 is broader than each of areas of the peripheral region 3b which are located along the long sides of the bottom wall 3. Therefore, a diameter of a base area of each through-hole 21 arranged along the narrow side of the bottom wall 3 is longer than a diameter of a base area of each through-hole 22 arranged along the long side of the bottom wall 3. Furthermore, the through-holes 21 provided along the narrow sides of the bottom wall 3 are arranged equally spaced apart. The through-holes 22 provided along the long sides of the bottom wall 3 are also arranged equally spaced apart.

Next, in another variation of the optical device 1 which is shown in FIG. 3, a series of through-holes 23 each having a trench shape are arranged along the peripheral region 3b of the bottom wall 3. Here, in this variation of the first embodiment, the center region 3a and the peripheral region 3b of the bottom wall 3 are separated by the through-holes 23, and the regions 3a and 3b are connected to each other via the sealant 16. It is also possible that a part of the through-holes 23 has a connection part (not shown) for connecting the center region 3a to the peripheral region 3b on the bottom wall 3.

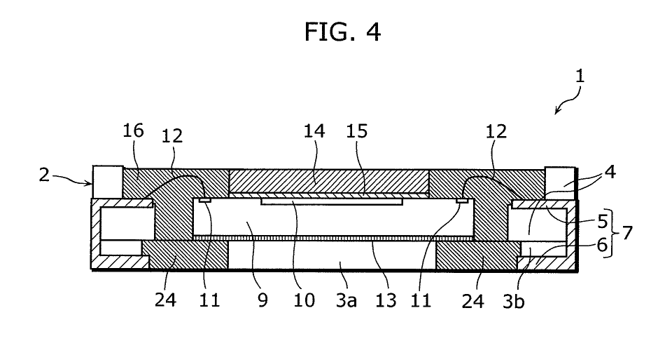

Next, in still another variation of the optical device 1 which is shown in FIG. 4, each of the through-holes 24 penetrates the peripheral region 3b of the bottom wall 3 and also extends to the center region 3a and under the side wall 4. When the through-holes 24 extend to below the optical element 9 (namely, the center region 3a) and under the side wall 4 as described above, a total area (surface area) of the through-holes 24 (a sum of surface areas of all through-holes 24) is increased. As a result, stress applied on the sealant 16 can be effectively dispersed.

Here, even in the case where the through-holes 24 extend to the center region 3a and under the side wall 4, it is desirable that a part of an upper opening of each through-hole 24 is located in the peripheral region 3b. With the structure, as described below, the material of the sealant 16 can be filled into the through-hole 24 after adhering the optical element 9 to the bottom wall 3 of the case 2.

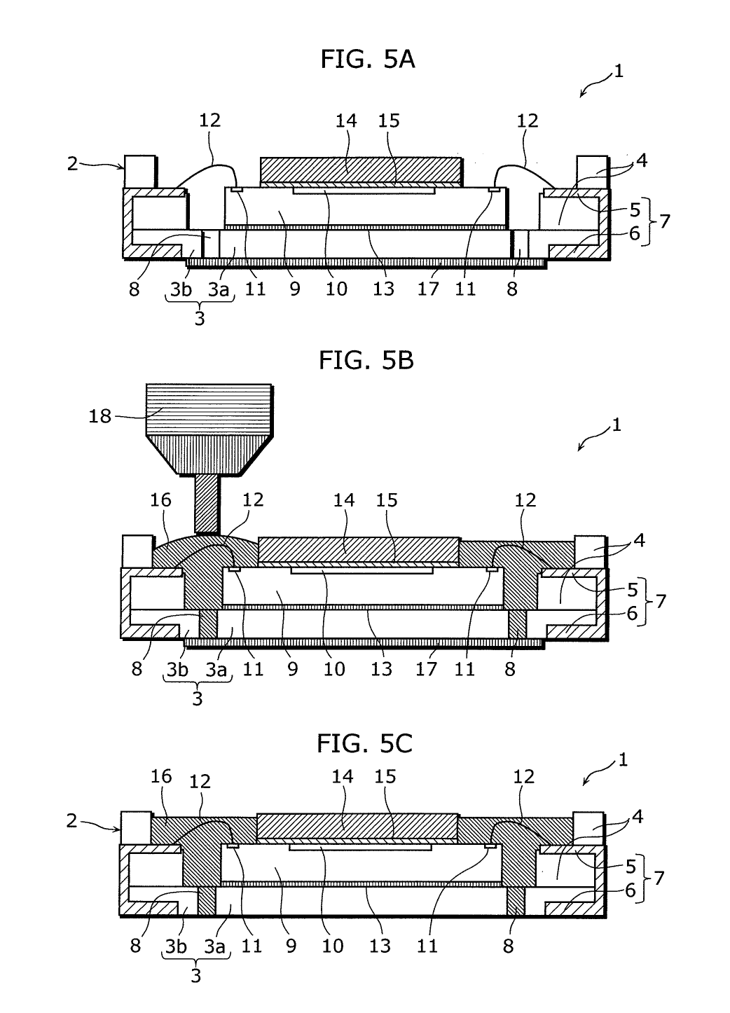

A method of manufacturing the optical device 1 according to the first embodiment of the present invention is described with FIGS. 5A to 5C.

Firstly, as shown in FIG. 5A, the optical element 9 is adhered to the bottom wall 3 of the recessed case 2. More particularly, the transparent member 14 is previously adhered to the upper surface of the optical element 9 so as to cover the light-receiving unit 10. Then, the bottom surface of the optical element 9 is adhered to the center region 3a of the bottom wall 3 using the DB substance 13. In addition, each of the internal electrodes 5 in the lead parts 7 is connected to a corresponding electrode part 11 of the optical element 9 using a corresponding wire 12.

Next, at this stage, the through-holes 8 formed in the bottom wall 3 of the case 2 are sealed on the bottom surface of the bottom wall 3. In more detail, a resin blocking tape 17 previously puts on the bottom surface of the case 2 in order to block openings of the through-holes 8. This process may be performed before adhering the optical element 9 to the case 2 or after adhering the optical element 9 to the case 2.

Next, as shown in FIG. 5B, in the optical device 1 in the situation of FIG. 5A, the material of the sealant 16 is filled into the recessed case 2 using a resin filling nozzle 18. When the sealant 16 has been filled, the sealant 16 is applied with head to be hardened.

Here, since the resin blocking tape 17 puts on the bottom surface of the case 2, the sealant 16 is not leaked from the through-holes 8. Furthermore, since the through-holes 8 are arranged in the peripheral region 3b, the upper openings of the through-holes 8 are not sealed by the optical element 9. In other words, the upper openings are opened. Therefore, the sealant 16 can be filled also into the through-holes 8 by only a single filling process.

Next, as shown in FIG. 5C, the filled sealant is heated to be hardened, and then the resin blocking tape 17 is removed. As a result, the optical device 1 according to the first embodiment of the present invention can be manufactured. It should be noted that, in the process shown in FIG. 5A, the means for blocking the through-holes 8 on the bottom surface of the bottom wall 3 is not limited to the resin blocking tape 17. However, it is desirably capable of being easily removed (capable of releasing the blocking) in the process shown in FIG. 5C.

The above-described processes can prevent the sealant 16 from leaking from the through-holes 8 when the material of the sealant 16 is filled into the recessed case 2.

Although only some exemplary embodiment and variations of the present invention have been described in detail above with reference of the drawings, those skilled in the art will readily appreciate that many modifications are possible in the exemplary embodiment and variations without materially departing from the novel teachings and advantages of the present invention. Accordingly, all such modifications are intended to be included within the same or equivalent scope of the present invention.

### INDUSTRIAL APPLICABILITY

The optical device according to the present invention is capable of ensuring optical high quality and high reliability of miniaturized packages, and therefore useful especially for small electronic devices.

What is claimed is:

1. An optical device comprising:
an optical element including a light-receiving element as a part of an upper surface of said optical element;
a transparent member disposed on the upper surface of said optical element so as to cover said light-receiving element;
a case including
a bottom wall,
a side wall protruding from an outer edge of said bottom wall, and
a through-hole penetrating said bottom wall,
said optical element and said transparent member being stored in a region between said bottom wall and said side wall; and
a sealant filled in (a) a space defined by surfaces of said optical element, said transparent member, and said case, and (b) said through-hole, said sealant being filled to the region to seal the space,
wherein said bottom wall of said case is segmented into (a) a center region in which said optical element is placed and (b) a peripheral region outside said center region, and
said through-hole is arranged in said peripheral region.

2. The optical device according to claim 1,
wherein said sealant is made of a light-shielding material.

3. The optical device according to claim 1,
wherein said through-hole is arranged across said peripheral region and said center region of said bottom wall.

4. The optical device according to claim 1,
wherein said through-hole extends to under said side wall.

5. A solid-state imaging device comprising:
a solid-state imaging element including a light-receiving element as a part of an upper surface of said solid-state imaging element;
a transparent member disposed on the upper surface of said solid-state imaging element so as to cover said light-receiving element;
a case including
a bottom wall,
a side wall protruding from an outer edge of said bottom wall, and
a through-hole penetrating said bottom wall,
said solid-state imaging element and said transparent member being stored in a region between said bottom wall and said side wall; and
a sealant filled in (a) a space defined by surfaces of said solid-state imaging element, said transparent member, and said case, and (b) said through-hole, said sealant being filled to the region to seal the space,
wherein said bottom wall of said case is segmented into (a) a center region in which said solid-state imaging element is placed and (b) a peripheral region outside said center region, and
said through-hole is arranged in said peripheral region.

6. A method of manufacturing an optical device,
the optical device including:
an optical element including a light-receiving element as a part of an upper surface of said optical element;
a transparent member disposed on the upper surface of said optical element so as to cover said light-receiving element;
a case including
a bottom wall,
a side wall protruding from an outer edge of said bottom wall, and
a through-hole penetrating said bottom wall,
said optical element and said transparent member being stored in a region between said bottom wall and said side wall; and
a sealant filled in (a) a space defined by surfaces of said optical element, said transparent member, and said case, and (b) said through-hole, said sealant being filled to the region to seal the space,
wherein said bottom wall of said case is segmented into (a) a center region in which said optical element is placed and (b) a peripheral region outside said center region, and
said through-hole is arranged in said peripheral region,
said method comprising:
adhering a bottom surface of the optical element on which the transparent member is deposited to the bottom wall of the case;
blocking the through-hole at a bottom surface of the bottom wall; and
filing the sealant into the region between the bottom wall and the side wall of the case.
